(19) United States
(12) Patent Application Publication
(10) Pub. No.: US 2011/0042774 A1
(43) Pub. Date: Feb. 24, 2011

(54) Film Sensor and Method for Producing a Film Sensor

(76) Inventors: Gerald Kloiber, Feldkirchen (AT); Heinz Strallhofer, Deutschlandsberg (AT); Joerg Haut, Deutschlandsberg (AT); Lutz Kirsten, Deutschlandsberg (AT)

Correspondence Address: SLATER & MATSIL, L.L.P., 17950 PRESTON RD, SUITE 1000, DALLAS, TX, 75252-5793, US

(21) Appl. No.: 12/862,571

(22) Filed: Aug. 24, 2010

Related U.S. Application Data
(63) Continuation of application No. PCT/EP2009/052944, filed on Mar. 12, 2009.

(30) Foreign Application Priority Data
Mar. 19, 2008 (DE) 10 2008 014 923.3

(51) Int. Cl. H01L 29/84; H01L 21/60

(52) U.S. Cl. 257/467; 438/119; 257/E29.324; 257/E21.514

(57) ABSTRACT

A film sensor having a first carrier film with at least one first conductor track is disclosed. The film sensor has a second carrier film which has at least one second conductor track. At least one electrical component is arranged between the first carrier film and the second carrier film. The electrical component has the properties of a functional ceramic. The electrical component is electrically contact-connected by means of at least one first conductor track and at least one second conductor track.

This application is a continuation of co-pending International Application No. PCT/EP2009/052944, filed Mar. 12, 2009, which designated the United States and was not published in English, and which claims priority to German Application No. 10 2008 014 923.3, filed Mar. 19, 2008, both of which applications are incorporated herein by reference.

### TECHNICAL FIELD

The invention relates to a film sensor for detecting a physical variable.

### BACKGROUND

The document U.S. Pat. No. 4,317,367 discloses a film sensor.

### SUMMARY

In one aspect, the present invention specifies a film sensor that can be produced in a simple and cost-effective manner.

In one embodiment, a film sensor has a first carrier film having at least one first conductor track. The first conductor track is preferably directly applied to the first carrier film in the form of a conductive layer. The film sensor also contains a second carrier film that has at least one conductor track. This second conductor track of the film sensor is preferably directly applied to the second carrier film. At least one electrical component is arranged between the first carrier film and the second carrier film. The electrical component preferably has the properties of a functional ceramic. The electrical component is preferably electrically contact-connected by means of the first conductor track and the second conductor track.

The first carrier film and the second carrier film are mechanically connected to one another. The carrier films are preferably connected to one another by means of a welded seam. The welding can be carried out either in a linear manner or else in an areal manner. A hot-stamping method or an ultrasonic welding method, for example, is used for this purpose.

The electrical component is preferably a ceramic temperature sensor which has a negative temperature coefficient. The electrical component preferably comprises a ceramic which has a metalized layer on two opposite sides. The electrical component preferably has the shape of a cuboid, the cuboid comprising a metalized layer on the top side and underside. In one embodiment, the size of the base area of the electrical component is approximately 0.5*0.5 mm. In another embodiment, the size of the base area of the electrical component may also be up to 2.0*2.0 mm. The thickness of the electrical component is approximately 0.4 to 0.6 mm. In one preferred embodiment, the ceramic of the electrical component comprises a metal oxide ceramic. However, it is also possible for the ceramic to also comprise other suitable materials. The metalized layer may have gold, for example. Furthermore, it is also possible for the metalized layer to have nickel, silver or other metals.

Furthermore, for the purpose of electrical contact-connection, the electrical component is preferably also mechanically connected to the conductor tracks. The electrical component can be mechanically connected to the conductor tracks, for example, by means of a conductive adhesive, which comprises silver, or a solder.

The electrical component is preferably completely surrounded toward the outside by the two carrier films. The carrier films almost completely terminate the electrical component toward the outside. The electrical component is thus protected from corrosive influences of the environment.

The carrier films preferably consist of a plastic. Polypropylene, for example, is suitable in this case. Furthermore, however, other plastics which are suitable for allowing conductor tracks to be applied to the carrier film, for example, by means of hot-stamping or electrodeposition, are also possible.

The carrier films preferably have a thickness in the range between 50 and 500 nm. In one preferred embodiment, the carrier films have a thickness between 200 and 300 nm.

The conductor tracks preferably contain copper. However, it is also possible for the conductor tracks to consist of another electrically conductive material.

In one preferred embodiment, the carrier films have a region in which the conductor tracks can be contact-connected from the outside. The regions are preferably arranged in such a manner that, if the carrier films are placed on top of one another, the conductor tracks can be contact-connected from the outside at the ends of the carrier films. The electrical connecting region of the film sensor is preferably arranged at that end of the film sensor which is opposite the end with the electrical component. The film sensor can therefore be electrically contact-connected via the exposed ends of the conductor tracks, sufficient stability of the contact region also being ensured by the carrier films.

In order to produce a film sensor, a method having the following steps is specified: at least one conductor track is applied to two provided carrier films in each case. An electrical component is then electrically contact-connected on the conductor tracks. The carrier films are subsequently mechanically connected to one another, the electrical component being situated between the two carrier films.

The conductor tracks are applied to the carrier films by means of hot-stamping, for example.

In another embodiment, the conductor tracks are applied to the carrier films by means of electrodeposition.

However, it is also possible to apply the electrical conductor tracks to the carrier films by means of other suitable methods.

The electrical component is electrically contact-connected to the conductor tracks by means of a conductive adhesive. However, it is also possible to connect the electrical component to the conductor tracks by means of a solder.

The carrier films are preferably connected to one another by means of ultrasonic welding.

In another embodiment, the carrier films can also be connected to one another by means of hot-stamping.

The electrical component is thus sealed toward the outside with respect to environmental influences by the two carrier films.

A method as described above can therefore be used to produce a film sensor which has a simple construction and can be produced in a cost-effective manner with few method steps.

The film sensor is preferably used as a clinical thermometer. In this case, polypropylene is particularly well suited as the material for the carrier films. Polypropylene has approval from the US Food and Drug Administration, for example, and therefore meets the requirements for medical purposes. For these purposes, the film sensor has an operating range of between −25° C. and 50° C., for example. In principle, however, it is also possible for the film sensor to have a larger operating range. The operating range is predominantly dependent on the material of the carrier films and on the temperature sensor used.

### BRIEF DESCRIPTION OF THE DRAWINGS

The items and methods described above are explained in more detail using the following figures and exemplary embodiments.

The drawings described below should not be interpreted as being true to scale. Rather, individual dimensions may be illustrated in enlarged, reduced or else distorted form for the purpose of better illustration. Elements which resemble one another or undertake the same function are denoted using the same reference symbols.

FIG. 1 diagrammatically shows a first carrier film having a first conductor track and an electrical component;

FIG. 2 diagrammatically shows a second carrier film having a second conductor track;

FIG. 3 diagrammatically shows a film sensor in a view from above, having an electrical component which is contact-connected by means of two conductor tracks;

FIG. 4 diagrammatically shows a side view of a film sensor; and

FIG. 5 diagrammatically shows the contact region of the film sensor.

The following list of reference symbols can be used in conjunction with the drawings:
1 First carrier film
2 First conductor track
3 Second carrier film
4 Second conductor track
5 Electrical component

### DETAILED DESCRIPTION OF ILLUSTRATIVE EMBODIMENTS

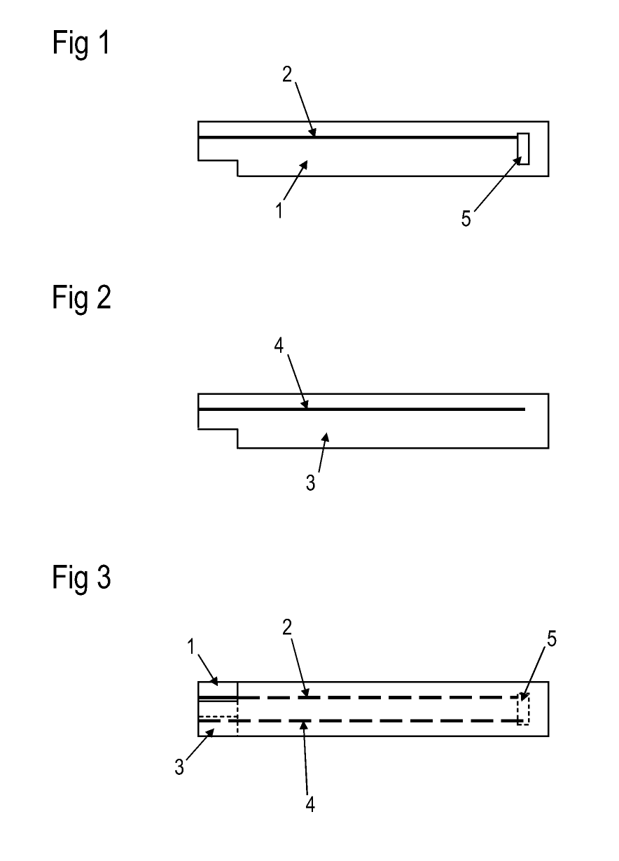

FIG. 1 shows a diagrammatic sketch of a first carrier film 1 of an exemplary embodiment of the film sensor. A first conductor track 2 is applied to the first carrier film 1. The first conductor track 2 is preferably applied to the first carrier film 1 by means of hot-stamping or electrodeposition. The first conductor track 2 can also be introduced into the surface of the first carrier film 1, with the result that part of the first conductor track 2 is arranged in a depression in the first carrier film 1.

When applying the first conductor track 2 by means of hot-stamping, the first conductor track 2 is partially introduced into the first carrier film 1 as a result of brief incipient melting of the surface of the first carrier film 1.

An electrical component 5 is arranged on the first carrier film 1. The first conductor track 2 is preferably arranged in such a manner that the first conductor track 2 at least partially projects from the first carrier film 1 at least in the region of the electrical component 5 or in the region of the electrical contacts of the electrical component 5. The first conductor track 2 preferably projects from the first carrier film 1 to such an extent that it is ensured that the electrical component 5 is sufficiently well connected to the first conductor track 2.

The electrical component 5 is preferably arranged in an end region of the elongated first carrier film 1. The electrical component 5 is preferably arranged in such a manner that it is at a sufficient distance from the edge of the first carrier film 1, such that the welded joint is arranged between the two carrier films 1, 3, preferably around the electrical component 5.

The electrical component 5 is preferably mechanically connected to the first conductor track 2 by means of an electrically conductive adhesive. The electrical component 5 can also be connected to the first electrical conductor track 2 by means of a solder. The mechanical connection between the first electrical conductor track 2 and the electrical component 5 is also used to electrically contact-connect the electrical component 5 to the first conductor track 2.

FIG. 2 illustrates a diagrammatic sketch of a second carrier film 3 of an exemplary embodiment of the film sensor. The second carrier film 3 has a second conductor track 4. As already described above in FIG. 1 for the first conductor track 2, the second conductor track 4 can be introduced onto or partially into the second carrier film 3.

FIG. 3 illustrates a diagrammatic view of an exemplary embodiment of a film sensor from above. The first carrier film 1 and the second carrier film 3 of the film sensor are placed on top of one another, with the result that the first carrier film 1 and the second carrier film 3 preferably overlap in an approximately flush manner. The conductor tracks 2, 4 of the carrier films 1, 3 are preferably arranged in such a manner that the first conductor track 2 and the second conductor track 4 do not come to lie on top of one another when placing the first carrier film 1 and the second carrier film 3 on top of one another. The first conductor track 2 and the second conductor track 4 are preferably laterally at a distance from one another. The first conductor track 2 and the second conductor track 4 are preferably arranged parallel to one another. The distance between the first conductor track 2 and the second conductor track 4 preferably approximately corresponds to the distance between the electrical contacts of the electrical component 5 at least in the region of the electrical component 5.

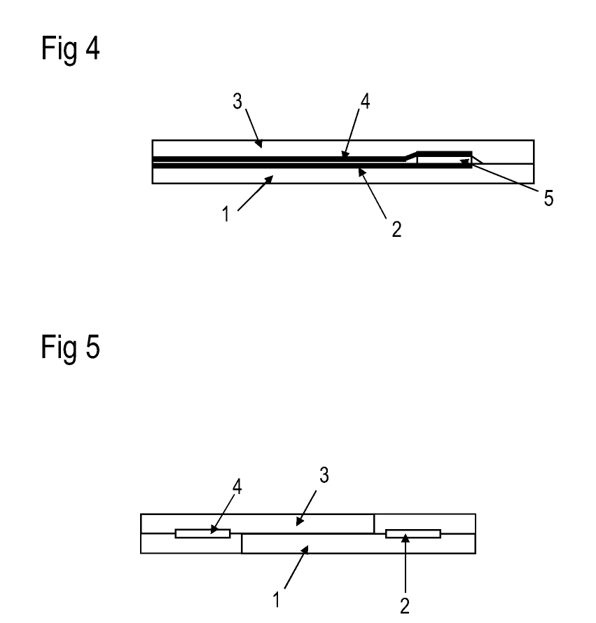

FIG. 4 shows a diagrammatic side view of an exemplary embodiment of a film sensor. The film sensor has a first carrier film 1 with a first conductor track 2 and a second carrier film 3 with a second conductor track 4. An electrical component 5 is arranged between the carrier films 1, 3. The electrical component 5 is preferably arranged in the end region of the carrier films 1, 3, the electrical component 5 preferably being arranged in such a manner that it is at a distance from the edge of the carrier films 1, 3. The carrier films 1, 3 seal the electrical component 5 toward the outside on all sides. The electrical component 5 is thus protected from corrosion caused by environmental influences. The conductor tracks 2, 4 illustrated in FIG. 4 are not arranged directly on top of one another but rather have a lateral offset with respect to one another, as also illustrated in FIG. 3.

FIG. 5 shows a diagrammatic sketch of the end region of a film sensor. The film sensor has two carrier films 1, 3 which are mechanically connected to one another. The carrier films 1, 3 are preferably arranged on top of one another, conductor tracks 2, 4 being arranged on the carrier films 1, 3. The conductor tracks 2, 4 are preferably arranged on the side of the carrier films 1, 3 which face one another. Sufficient insulation between the conductor tracks 2, 4 is ensured by a lateral offset between the conductor tracks 2, 4. The ends of the carrier films 1, 3 having the conductor tracks 2, 4 are exposed in the end region of the film sensor which is illustrated in FIG. 5. In this region, the ends of the conductor tracks 2, 4 are freely accessible from the outside from at least one side and can therefore be electrically contact-connected. As a result of the fact that the conductor tracks 2, 4 are supported by the carrier films 1, 3 from at least one side in the end region, the contact region of the film sensor has sufficiently high stability. The contact region of the film sensor can therefore be inserted, for example, into an appropriate connection contact without the ends of the conductor tracks 2, 4 being bent over or damaged in some other manner.

Although it was possible to describe only a restricted number of possible developments of the invention in the exemplary embodiments, the invention is not restricted to these developments. In principle, it is possible for the film sensor to have more than one electrical component or a plurality of conductor tracks, with the result that two electrical components have a common first conductor track, for example, and, separately from each other, each have a further, second conductor track.

The invention is not restricted to the number of elements illustrated.

The description of the items specified here is not restricted to the individual specific embodiments, rather the features of the individual embodiments can be combined with one another as desired, insofar as is technically useful.

What is claimed is:

1. A film sensor comprising:
a first carrier film which has a first conductor track;
a second carrier film which has a second conductor track;
an electrical component arranged between the first carrier film and the second carrier film,
wherein the electrical component has properties of a functional ceramic, and
wherein the electrical component is electrically contact-connected by the first conductor track and the second conductor track.

2. The film sensor as claimed in claim 1, wherein the first carrier film and the second carrier film are mechanically connected to one another.

3. The film sensor as claimed in claim 1, wherein the electrical component has a negative temperature coefficient.

4. The film sensor as claimed in claim 1, wherein the electrical component is mechanically connected to the first conductor track and the second conductor track.

5. The film sensor as claimed in claim 1, wherein the electrical component is completely surrounded by the first and second carrier films.

6. The film sensor as claimed in claim 1, wherein the first and second carrier films each comprise a plastic.

7. The film sensor as claimed in claim 6, wherein the first and second carrier films each comprise polypropylene.

8. The film sensor as claimed in claim 1, wherein the first conductor track and the second conductor track each comprise copper.

9. The film sensor as claimed in claim 1, wherein the first conductor track and the second conductor track is able to be electrically contact-connected from outside the film sensor.

10. A method for producing a film sensor, the method comprising:
providing first and second carrier films, each carrier film including at least one conductor track applied thereto;
contact-connecting an electrical component to the conductor tracks of the first and second carrier films; and
after contact-connecting, mechanically connecting the first and second carrier films so that the electrical component is enclosed between the first and second carrier films.

11. The method as claimed in claim 10, wherein providing the first and second carrier films comprises applying a first conductor track to the first carrier film and applying a second conductor track to the second carrier film.

12. The method as claimed in claim 11, wherein the first and second conductor tracks are each applied by means of hot-stamping.

13. The method as claimed in claim 11, wherein the first and second conductor tracks are each applied by means of electrodeposition.

14. The method as claimed in claim 10, wherein contact-connecting the electrical component comprises contact-connecting the electrical component to the first and second conductor tracks with a conductive adhesive.

15. The method as claimed in claim 10, wherein mechanically connecting the first and second carrier films comprises ultrasonic welding.

16. The method as claimed in claim 10, wherein mechanically connecting the first and second carrier films comprises hot-stamping.
